(19) United States
(12) Patent Application Publication
(10) Pub. No.: US 2008/0277798 A1
(43) Pub. Date: Nov. 13, 2008

(54) SEMICONDUCTOR DEVICE AND METHOD FOR MANUFACTURING THE SAME

(76) Inventors: Sang-Hee Lee, Eumseong-gun (KR); Gab Hwan Cho, Icheon-si (KR)

Correspondence Address: SHERR & VAUGHN, PLLC, 620 HERNDON PARKWAY, SUITE 200, HERNDON, VA, 20170, US

(21) Appl. No.: 12/115,628

(22) Filed: May 6, 2008

(30) Foreign Application Priority Data
May 10, 2007 (KR) 10-2007-0045625

(51) Int. Cl. H01L 23/52; H01L 21/4763

(52) U.S. Cl. 257/773; 438/622; 257/E21.495; 257/E23.141

(57) ABSTRACT

A semiconductor device and a method for manufacturing the same. The semiconductor device includes a first main pattern formed on a substrate and a first dummy pattern formed in a parallel direction to a first main pattern on a layer on which the first main pattern is formed. Additional dummy patterns can be inserted and pattern density can be increased by the insertion of the dummy pattern in consideration of the shape and direction of the main pattern per the metal layer.

This application claims priority under 35 U.S.C. 119 to Korean Patent Application No. 10-2007-0045625 (filed on May 10 2007), which is hereby incorporated by reference in its entirety.

### BACKGROUND

A semiconductor device may have a multi-layer structure such that each layer of the multi-layer structure is formed by a sputtering method or a chemical vapor deposition method, etc. and is patterned through a lithography process.

Since there are many problems due to differences in pattern size or pattern density on a substrate of a semiconductor device, a technology forming the dummy pattern and a main pattern together has been developed.

### SUMMARY

Embodiments relate to a semiconductor device and a method for manufacturing the same, capable of providing a dummy pattern with a new structural shape or configuration.

Embodiments relate to a semiconductor device and a method for manufacturing the same, capable of assuring uniformity of a pattern.

Embodiments relate to a semiconductor device and a method for manufacturing the same, capable of increasing pattern density.

Embodiments relate to a semiconductor device and a method for manufacturing the same, capable of simplifying a design process and a manufacturing process.

Embodiments relate to a semiconductor device that can include at least one of the following: a first main pattern formed on a substrate; and a first dummy pattern formed in a parallel direction to the first main pattern on a layer which the main pattern is formed.

Embodiments relate to a semiconductor device that can include at least one of the following: a second main pattern formed in a vertical direction to the first main pattern on different layer from a layer on which the first main pattern is formed; and a second dummy pattern formed in a parallel direction to the second main pattern on a layer on which the second main pattern is formed.

Embodiments relate to a method for manufacturing a semiconductor device that can include at least one of the following steps: forming a first main pattern on a substrate; and then forming a first dummy pattern in a parallel direction to the first main pattern on a layer on which the first main patter is formed.

### DRAWINGS

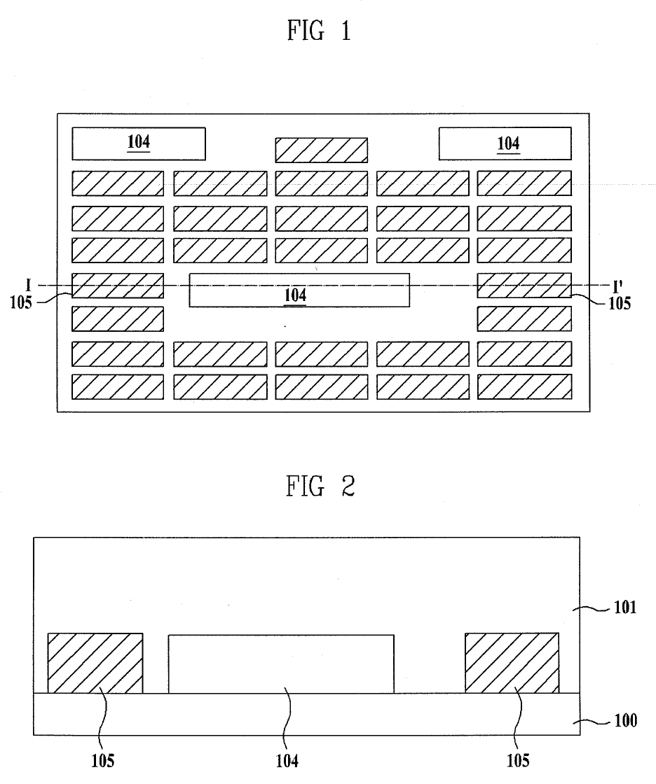

Example FIGS. 1 to 4 illustrate a semiconductor device, in accordance with embodiments.

### DESCRIPTION

As illustrated in example FIG. 1, in accordance with embodiments a semiconductor device can include first main pattern 104 and first dummy pattern 105. First main pattern 104 can be formed on and/or over semiconductor substrate 100 (hereinafter, referred to as a substrate). First dummy pattern 105 can be formed in a direction parallel to first main pattern 104 on and/or over a layer on and/or over which first main pattern 104 is formed.

In accordance with embodiments, dummy pattern 105 can be inserted in consideration of shape and directivity of main pattern 104 per a metal layer. Therefore, a region into which dummy pattern 105 is inserted can be assured as well as pattern density can be increased.

For example, as illustrated ion example FIGS. 1 and 2, which includes a semiconductor device wherein an odd^{th} (or even^{th}) metal layer can be formed. In this case, first main pattern 104, which is the odd^{th} metal pattern, can be formed in a horizontal direction. First dummy pattern 105 can be formed in a direction parallel to first main pattern 104. Consequently, the region into which the dummy pattern is inserted can be assured as well as the pattern density can be increased.

The semiconductor device can further include first interlayer dielectric layer 101 formed on and/or over substrate 100 including first main pattern 104 and first dummy pattern 105. First interlayer dielectric layer 101 can be configured as a single layer or a multi-layer structure.

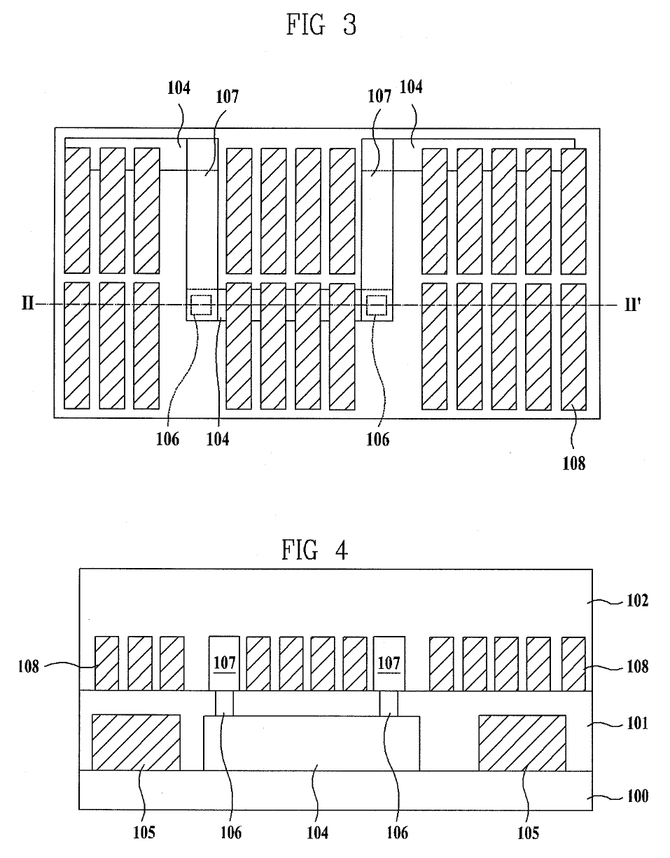

As illustrated in example FIGS. 3 and 4, in accordance with embodiments, a semiconductor device as illustrated and described in example FIGS. 1 and 2 can further include second main pattern 107 and second dummy pattern 108. Second main pattern 107 can be formed in a direction perpendicular to first main pattern 104 on and/or over a different layer from the layer on and/or over which first main pattern 104 is formed. Second dummy pattern 108 can be formed in a parallel direction to second main pattern 107 on and/or over the layer on and/or over which second dummy pattern 108 is formed.

In the semiconductor device according to embodiments illustrated in example FIGS. 3 and 4, second dummy pattern 108 can be inserted in consideration of shape and directivity of second main pattern 107 per the metal layer. Therefore, the region into which the dummy pattern is inserted can be assured as well as the pattern density can be increased.

For example, in FIGS. 3 and 4, second main pattern 107, which is the even^{th} (or odd^{th}) metal pattern, can be formed in a vertical direction relative to first main pattern 104. Therefore, second dummy pattern 108 can be formed in a parallel direction to second main pattern 107. Consequently, the region into which the second dummy pattern is inserted can be assured as well as the pattern density can be increased.

As illustrated in example FIGS. 1 to 4, at least one of first main pattern 104 and second main pattern 107 can be the metal pattern, and at least one of first dummy pattern 105 and second dummy pattern 108 can be the metal dummy pattern, but is not limited thereto.

Third main pattern 106 can be formed electrically connecting first main pattern 104 and second main pattern 107. Third main pattern 106 can be a contact pattern, but is not limited thereto. Second interlayer dielectric layer 102 can be formed on and/or over first interlayer dielectric layer 101 and on and/or over second main pattern 107 and second dummy pattern 108. Second interlayer dielectric layer 102 can be configured as a single layer or a multi-layer structure.

Hereinafter, a method for manufacturing the semiconductor device according to the embodiment of the present invention will be described with reference to example FIGS. 1 to 4.

In a description of the embodiment of the present invention, a sequence of a manufacturing process is only one example and a process performed by a combination of various methods belongs to the scope of the appended claims.

First main pattern 104 can be formed on and/or over semiconductor substrate 100. First main pattern 104 can be a metal pattern, but is not limited thereto. When first main pattern 104 is the odd^{th} (even^{th}) metal pattern, it can be formed in a horizontal direction, but is not limited thereto.

First dummy pattern 105 can then be formed in a parallel direction to first main pattern 104 on and/or over the layer on and/or over which first main pattern 104 is formed. Therefore, first dummy pattern 105 can be formed in a parallel direction to first main pattern 104 so that the region into which the dummy pattern is inserted can be assured and the pattern density can be increased. First main pattern 104 and first dummy pattern 105 can be formed simultaneously.

First interlayer dielectric layer 101 can then be formed on and/or over substrate 100 including first main pattern 104 and second dummy pattern 105.

Third main pattern 106, which electrically connects first main pattern 104 and second main pattern 107, can then be formed. Third main pattern 106 can be a contact pattern. After first interlayer dielectric layer 101 is formed, a hole for forming third main pattern 106 can be formed in first interlayer dielectric layer 101 by a photolithography process, and then third main pattern 106 can be completed by performing a planarization process after a material for third main pattern 106, for example, a metal layer is buried in the formed hole.

Second main pattern 107 can then be formed on and/or over third main pattern 106 in a direction perpendicular to first main pattern 104 on a different layer from the layer on and/or over which first main pattern 104 is formed. For example, second main pattern 107, which is an even^{th} (or odd^{th}) metal pattern, can be formed in a vertical direction relative to first main pattern 104.

Second dummy pattern 108 can then be formed in a parallel direction to second main pattern 107 on and/or over the layer on and/or over which second main pattern 107 is formed. Therefore, second dummy pattern 108 can be formed in a parallel direction to second main pattern 107 so that the region into which the dummy pattern is inserted can be assured and the pattern density can be increased. Second main pattern 107 and second dummy pattern 108 can be formed simultaneously.

Hereinafter, second interlayer dielectric layer 102 can be formed on and/or over first interlayer dielectric layer 101 including second main pattern 107 and second dummy pattern 108.

In accordance with embodiments, a semiconductor device can include additional dummy patterns while increasing the pattern density by the insertion of the dummy pattern in consideration of the shape and direction of the main pattern per metal layer. Pattern uniformity can be increased by forming the dummy pattern in the same direction as the main pattern. A constant critical diameter (CD) of each pattern can be obtained according the assurance of the pattern uniformity, and the design process and manufacturing process can be simplified according to the regular direction of the main pattern and the dummy pattern by forming the dummy pattern in the same direction as the main pattern.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a first main pattern formed on a substrate; and
a first dummy pattern formed in a parallel direction to the first main pattern on a layer which the main pattern is formed.

2. The semiconductor device of claim 1, further comprising:
a second main pattern formed in a direction perpendicular to the first main pattern on a different layer than the layer on which the first main pattern is formed; and
a second dummy pattern formed in a parallel direction to the second main pattern and on the same layer as the second main pattern.

3. The semiconductor device of claim 2, further comprising a third main pattern electrically connecting the first main pattern to the second main pattern.

4. The semiconductor device of claim 2, wherein at least one of the first main pattern and the second main pattern is a metal pattern.

5. The semiconductor device of claim 4, wherein at least one of the first dummy pattern and the second dummy pattern is a metal dummy pattern.

6. The semiconductor device of claim 5, wherein the third main pattern is a contact pattern.

7. The semiconductor device of claim 2, further comprising a first interlayer dielectric layer formed on the semiconductor substrate including the first main pattern and the first dummy pattern.

8. The semiconductor device of claim 7, further comprising a second interlayer dielectric layer formed on the first interlayer dielectric layer including the second main pattern and the second dummy pattern.

9. A method for manufacturing a semiconductor device comprising:
forming a first main pattern on a substrate; and then
forming a first dummy pattern in a parallel direction to the first main pattern on a same layer on which the first main patter is formed.

10. The method of claim 9, further comprising:
forming a second main pattern in a direction perpendicular to the first main pattern on a different layer from the layer on which the first main pattern is formed; and then
forming a second dummy pattern in a parallel direction to the second main pattern on the same layer on which the second main pattern is formed.

11. The method of claim 10, further comprising forming a third main pattern electrically connecting the first main pattern to the second main pattern.

12. The method of claim 11, wherein forming the third main pattern comprises:
forming a hole in the first interlayer dielectric layer; and then
filling the hole with a metal layer; and then
performing a planarization process on the metal layer.

13. The method of claim 12, wherein the hole is formed using a photolithography process.

14. The method of claim 10, wherein at least one of the first main pattern and the second main pattern is a metal pattern.

15. The method of claim 14, wherein at least one of the first dummy pattern and the second dummy pattern is a metal dummy pattern.

16. The method of claim 12, further comprising forming a first interlayer dielectric layer on the substrate including the first main pattern and the first dummy pattern.

17. The semiconductor device of claim 16, wherein the third main pattern is a contact pattern.

18. The method of claim 10, further comprising forming a second interlayer dielectric layer on the first interlayer dielectric layer including the second main pattern and the second dummy pattern.

19. A method for manufacturing a semiconductor device comprising:
forming a first main pattern on a substrate; and then
forming a first dummy pattern in a parallel direction to the first main pattern on a same layer on which the first main patter is formed; and then
forming a first interlayer dielectric layer on the substrate including the first main pattern and the first dummy pattern;
forming a third main pattern extending through the first interlayer dielectric layer to electrically connect the first main pattern to the second main pattern; and then
forming a second main pattern on the first interlayer dielectric layer in a direction perpendicular to the first main pattern; and then
forming a second dummy pattern on the first interlayer dielectric layer in a parallel direction to the second main pattern.

20. The method of claim 19, further comprising, after forming the second dummy pattern, forming a second interlayer dielectric layer on the substrate including the second main pattern and the second dummy pattern.
